(19) United States
(12) Patent Application Publication
(10) Pub. No.: US 2024/0355649 A1
(43) Pub. Date: Oct. 24, 2024

(54) PROCESS ASSEMBLY FOR SEMICONDUCTOR PROCESSING AND SEMICONDUCTOR PROCESSING METHOD

(71) Applicant: centrotherm international AG, Blaubeuren (DE)

(72) Inventors: Peter Völk, Blaubeuren (DE); Jan Dirk Kähler, Blaubeuren (DE)

(21) Appl. No.: 18/304,014

(22) Filed: Apr. 20, 2023

(51) Int. Cl. H01L 21/67

(52) U.S. Cl. CPC H01L 21/67109

(57) ABSTRACT

A process assembly is specifically suited for use in a semiconductor process, the integration of the process assembly for processing a semiconductor product, and a method for processing a semiconductor product. The process assembly has a hollow support tube that is formed with a slit. The slit runs along a longitudinal direction of the support tube. A hollow process tube provides a process volume for a semiconductor process. The process tube is arranged within the support tube, at least sectionally, such that the support tube supports the process tube.

### FIELD AND BACKGROUND OF THE INVENTION

The present invention relates to a process assembly, particularly for use in a semiconductor process, the integration of the process assembly for processing a semiconductor product, and a method for processing a semiconductor product.

In semiconductor production, elements fabricated from quartz (SiO₂) are frequently used due to their high purity. The limit of the material load capacity with regard to the operating temperature for such quartz elements is approximately 1,050° C. At temperatures above 1,050° C., quartz elements become plastically unstable. Therefore, at such temperatures, elements fabricated from silicon carbide (SiC) are usually used, potentially with a chemical vapor deposition (CVD) coating.

A common device for the high-temperature treatment of semiconductor substrates are so-called horizontal furnaces. Such furnaces usually comprise a horizontally arranged process tube, although vertical process tube arrangements are also known. For such horizontal furnaces, which operate at temperatures above 1,000° C., SiC process tubes are usually used. When arranged horizontally and operated continuously at operating temperatures above 1,000° C., process tubes fabricated from a material comprising quartz could deform under their own weight. In particular, such a quartz tube could undergo irreversible plastic deformation over time. This initially occurs by flattening the tube into an oval, i.e. the quartz tube become wider and flatter with increasing operating time. In addition, the top of the quartz tube could begin to cave in towards the center of the tube. Such deformation could impair the heat distribution inside the quartz tube. Also, the process volume defined inside the process tube could be deformed in such a way that substrates can no longer be received.

However, other disadvantages may be associated with the commonly utilized SiC process tubes. For example, SiC process tubes are many times more expensive than quartz process tubes. In addition, if oxygen is introduced into the SiC process tube, the inner surface of a SiC process tubes usually oxidizes forming a thin silicon oxide layer. This happens regardless of whether an additional SiC CVD layer has previously been deposited on the inner surface of the process tube or not. Said thin silicon oxide layer acts like a sink for unwanted materials such as metals. Consequently, these unwanted materials are difficult to remove from the process tube. Accordingly, there is a risk that such unwanted materials diffuse uncontrollably onto semiconductor substrates in the process tube during operation thereof.

Additionally, deformations of a heating element surrounding the process tube can cause sections of the SiC process tube to come into contact with the heating element. This could lead to a short circuit which, in addition to damaging the heating element, could also damage the SiC process tube.

### SUMMARY OF THE INVENTION

It is accordingly an object of the invention to provide a process assembly and a corresponding method which overcome at least some of the above-mentioned disadvantages of the heretofore-known devices and methods of this general type and which provide for robust and stable semiconductor processes over a long period of time with low expenditure.

These objects are achieved by the claimed process assembly for processing a semiconductor product, the integration of such a process assembly for processing a semiconductor product, and a method for processing a semiconductor product as claimed.

In other words, with the above and other objects in view there is provided, in accordance with the invention, a process assembly for processing a semiconductor product, the process assembly comprising:
a hollow support tube, said support tube being formed with a slit running along a longitudinal direction of said support tube; and
a hollow process tube defining a process volume for a semiconductor process, said process tube being arranged, at least sectionally, within said support tube and said support tube supporting said process tube.

A process assembly for processing a semiconductor product, particularly for use in a high temperature semiconductor process, according to a first aspect of the invention comprises a hollow support tube having a slit. Said slit runs along a longitudinal direction of the support tube. Further, a hollow process tube is provided, the process tube defining a process volume for a semiconductor process. According to the invention, the process tube is arranged at least sectionally within the support tube such that the support tube supports the process tube.

A longitudinal direction of the support tube in the sense of the present invention preferably corresponds the lengthwise extension of said tube. For example, the longitudinal direction is parallel to a center line of the process assembly, particularly of the support tube and/or of the process tube.

An aspect of the invention is based on the approach to support a process tube by arranging the process tube at least partially within the corresponding support tube. By this means, support tube and process tube can form a process assembly wherein the process tube bears against the support tube.

Preferably, the support tube is provided for stabilizing the shape of the process tube. For example, the process tube is arranged within the support tube such that the process tube bears against the support tube with at least a part of its circumference. Advantageously, the support tube is designed to sustain an annular cross section of the process tube even at high temperatures. Hence, the process tube can be operated even at temperatures exceeding its temperature stability threshold and/or over longer times without risking plastic deformation. This may not only prolong service life of the process tube and/or the process assembly as a whole, respectively, but also avoid or at least reduce costs and effort for maintenance and/or exchange of parts.

For maintaining shape of the process tube, it is advantageous for the support tube to have a higher dimensional stability than the process tube, in particular at high temperatures such as 1,100° C. and above. Particularly, it is preferable that the support tube has a higher resistance against temperature induced deformation than the process tube. For example, the support tube may be dimensionally stable up to temperatures of at least 1,300° C.

Because this usually requires fabrication of the support tube and the process tube from different materials, there is the risk of unequal thermal expansion with rising temperatures. Thus, in order to enable a stable support for the process tube over a wide temperature range, the support tube preferably comprises a slit running along a longitudinal direction of the support tube. This slit may provide or at least enhance elasticity of the support tube. Particularly, this allows the support tube to flexibly surround the process tube at least partially along its circumference. What is more, the support tube can cling to the process tube in a spring-like manner. By this means, the support tube may provide stabilization to the shape of the process tube, and at the same time accommodate thermal expansion of the process tube.

Further, by means of the slit, production-related gaps between the support tube and the process tube may be minimized. Thus, heat transfer from a heating unit arranged around the support tube to the support tube may be optimized accordingly. This allows for an improved temperature homogeneity in the process tube. In addition, the service life of the heating unit or heating cassettes can be increased, as short circuits via the process tube can be avoided.

Preferred embodiments of the invention and further aspects thereof are described below, each of which, unless expressly excluded, may be combined with each other and with the aspects of the invention described below as desired.

To be able to achieve a stable support of the process tube, an inner surface of the support tube preferably lies flat against an outer surface of the process tube at least sectionally. For example, a section of the outer surface of the process tube may bear directly against the inner surface of the support tube. Preferably, at least a section of the outer surface of the process tube directly contacts the inner surface of the support tube. This allows for an optimal load and heat transfer from the process tube to the support tube.

It is particularly preferred that the inner surface of the support tube at least sectionally lies flat against the outer surface of the process tube along at least a part of the circumference of the process tube. Advantageously, the support tube surrounds the process tube substantially along the whole circumference of the process tube. By this means, a homogeneous distribution of loads acting on the support tube can be achieved.

Such an arrangement of the process tube within the support tube can be achieved by arranging the support tube coaxial with the process tube. Thus, the support tube advantageously forms a shell of the process tube. This not only may increase stabilization by the support tube, but also facilitate assembly of the process tube within the support tube.

Advantageously, the support tube surrounds the process tube along the whole circumference of the process tube except in a section defined by the width of the slit. To allow for sufficient flexibility of the support tube in this arrangement, the slit preferably intersects the support tube over an entire length of the support tube. Such a continuous gap in the shell of the process tube may help to avoid problems arising due to different heat expansion coefficients of the support tube and the process tube in a particularly reliable manner.

Therein, a particularly high flexibility of the support tube can be achieved by having the width of the slit covering at least 2%, preferably at least 4%, further preferably at least 6%, of the outer circumference of the support tube. For example, at least in a section where the support tube supports the process tube, the inner surface of the support tube lies flat against the outer surface of the process tube along at most 98%, preferably at most 96%, further preferably at most 94%, of the circumference of the process tube.

Alternatively or additionally, a particularly stable support of the process tube can be achieved by having the width of the slit covering at most 10%, preferably at most 8%, further preferably at most 6%, of the outer circumference of the support tube. For example, at least in a section where the support tube supports the process tube, the inner surface of the support tube lies flat against the outer surface of the process tube along at least 90%, preferably at most 92%, further preferably at most 94%, of the circumference of the process tube.

Accordingly, in a preferred embodiment, the slit comprises a width of 10 mm or less, preferably 8 mm or less, further preferably 5 mm or less. Alternatively or additionally, the slit comprises a width of at least 1 mm or more, preferably 2 mm or more, further preferably 5 mm or more. Advantageously, the slit comprises a width between 1 mm and 10 mm.

In another preferred embodiment, the slit is nonlinear. For example, the slit may not run straight in the longitudinal direction, but rather deviate from the longitudinal direction. In particular, the slit may comprise turns and angles. It is conceivable that the slit meanders, e.g. in a sinusoidal manner, in the longitudinal direction. A nonlinear slit may help in reducing the risk or at least the extent of deformation of the support tube during operation of the process assembly.

Extensive testing showed that, when operated over long times at high temperatures of, say, 1,100° C., the longitudinal edges of the support tube defining the slit, i.e., the lateral ends of the support tube, may slightly move in the longitudinal direction relative to each other. Intensive operation thus may result in a deformation of the support tube similar to torsion. This deformation can be countered or at least reduced by having the support tube comprising at least one section in which the slit runs substantially perpendicular to the longitudinal direction or at least at an angle to the longitudinal direction. Such a design of the slit may provide additional stabilization in the longitudinal direction. In particular, in said section of the support tube, the opposite longitudinal edges of the support tube may come into contact upon the described deformation of the support tube, thereby obstructing the deformation from advancing further.

A particularly effective shape of the slit for suppressing or at least reducing torsional-like deformation can be achieved by interleaving the two longitudinal edges of the support tube. Preferably, when the slit is defined by two opposite longitudinal edges of the support tube, one of the edges comprises at least one projection which at least partially meshes with a corresponding recess in the opposite edge. For example, the edges may be toothed, wherein the teeth projecting from one edge protrude into the clearance between the teeth projecting from the opposite edge, and vice versa. Thus, the edges of the at least one projection or recess, respectively, perpendicular or at least angled to the longitudinal direction may lock upon longitudinal movement of the edges relative to each other.

In another preferred embodiment, the support tube comprises a bearing structure for bearing the support tube. For example, by means of the bearing structure, the support tube can be supported in a horizontal furnace, particularly inside a heating arrangement. Advantageously, the bearing structure is arranged on an outer surface of the support tube. For example, the bearing structure can be fastened to the outer surface. This way, obstruction of the operation of the process tube arranged within the support tube may be prevented. Further, the bearing structure can reliably transfer loads acting on the support tube.

Advantageously, the bearing structure is formed by a plurality of bearing elements. These bearing elements may be distributed along the circumference and/or along the length of the support tube. For example, the process assembly may comprise at least two bearing elements arranged on the outer surface of the support tube. This allows a selective load transfer, particularly a symmetrical load transfer, for example by symmetrical arrangement of the bearing elements on the outer surface.

Preferably, each of the bearing elements is arranged to bear the support tube along the whole length of the support tube. Thus, a homogeneous load distribution can be achieved. To this end, it is particularly preferred that each of the bearing elements bears the support tube along a line on the outer surface of the support tube.

For example, the at least two bearing elements can be arranged below a horizontal median plane of the support tube.

A horizontal median plane of the support tube in the sense of the present invention is preferably a horizontally oriented plane separating an upper half of the support tube from a lower half of the support tube. For example, the horizontal median plane is a horizontal plane in which lies the center line of the process assembly, particularly of the support tube and/or of the process tube. Preferably, the horizontal median plane lies perpendicular to a cross section of the process assembly, particularly of the support tube and/or of the process tube.

Providing the at least two bearing elements below the horizontal median plane therefore allows to provide a particularly stable support for the support tube.

In a preferred arrangement of the at least two bearing elements below the horizontal median plane, each of the at least two bearing elements is arranged at an angle of substantially 45° below the horizontal median plane of the support tube. Particularly, each of the two bearing elements may be arranged on a bisectrix between the horizontal median plane and a vertical median plane of the support tube.

A vertical median plane of the support tube in the sense of the present invention is preferably a vertically oriented plane separating a left half of the support tube from a right half of the support tube. For example, the vertical median plane is a vertical plane in which lies the center line of the process assembly, particularly of the support tube and/or of the process tube. Preferably, the vertical median plane lies perpendicular to a cross section of the process assembly, particularly of the support tube and/or of the process tube. In particular, the center line may define an intersection of the vertical median plane with the horizontal median plane. Accordingly, the horizontal median plane and the vertical median plane may define four sectors in a cross section of the support assembly, particularly of the support tube and/or of the process tube.

By arranging the at least two bearing elements at an angle of substantially 45° below the horizontal median plane, a stable and balanced support of the support tube can be realised.

In order to be able to achieve a particularly stable and balanced support, the at least two bearing elements are preferably arranged symmetrically with respect to the vertical median plane. For example, along a circumference of the support tube, an angle of substantially 45° may be provided between the vertical median plane and each of the bearing elements.

Alternatively or additionally, the at least two bearing elements may be arranged symmetrically with respect to the slit. In this embodiment, it is particularly preferred that the vertical median plane intersects the slit. Therein, the slit is preferably arranged above the horizontal median plane. Accordingly, the at least two bearing elements may advantageously be arranged such that along the circumference of the support tube, an angle of substantially 135° is provided between the slit and each of the bearing elements.

For achieving a particularly homogeneous load distribution, the at least two bearing elements are configured as rails running along the longitudinal direction. Particularly, each of the at least two bearing elements may comprise a massive or hollow elongated body with a cylindrical or rectangular cross-section. By this means, an equal load can be transferred through the bearing elements along the whole length of the bearing elements.

Preferably, the at least two bearing elements run along the whole length of the support tube. By this means, an equal load can be transferred through the bearing elements along the whole length of the support tube.

A particularly durable support of the process tube can be achieved by having the support tube and the bearing structure or the at least two bearing elements, respectively, fabricated in one piece. This can also facilitate fabrication of the support tube and bearing structure or at least two bearing elements, respectively.

Alternatively, the bearing structure or the at least two bearing elements, respectively, may be fastened to the support tube. For example, the bearing structure or the at least two bearing elements, respectively, may be screwed, welded, or otherwise mounted to the outer surface of the support tube. This may improve flexibility in the fabrication of the support tube and/or the bearing structure of the at least two bearing elements, respectively.

In yet another preferred embodiment, the process tube is fabricated from a material comprising quartz. This may facilitate fabrication of the process tube. Due to the arrangement of such a quartz tube in the support tube, a stable reaction chamber e.g. for semiconductor processes even at 1,100° C. and above may be achieved at low costs.

Alternatively or additionally, the support tube is fabricated from a material comprising a ceramic. For example, the support tube may be fabricated from a material comprising aluminum oxide (Al₂O₃). This not only allows for very good electrical insulation of the process tube, but also may secure very good thermal conductivity. Thus, the effort for achieving a predetermined process temperature in the process volume defined inside the process tube can be reduced.

Further, ceramics have high melting temperatures, for example of above 2,000° C. Specifically, aluminum oxide has a melting temperature of 2,072° C. Therefore, a support tube fabricated from a material comprising a ceramic may reliably stabilize the shape of the process tube even at temperatures of 1,100° C. and above.

An additional or alternative way of reducing the effort for providing a predetermined process temperature in the process volume is to provide the support tube with a reduced wall thickness compared to the process tube. For example, the wall thickness of the support tube may be less than 50%, preferably less than 30%, further preferably less than 10%, of a wall thickness of the process tube. Besides having an advantageous effect on heat conduction through the support tube, such wall thickness also may enhance elasticity of the support tube. With such a thin wall compared to the process tube wall, the support tube may be able to absorb thermal expansion of the process tube.

Heat may be transferred to the process tube, particularly to the process volume defined thereby, via the support tube. To this end, the process assembly preferably comprises a heating unit arranged circumferentially around the support tube. For example, a heating element may be helically wound around the support tube. By this means, homogeneous heating of the process volume can be achieved.

The process assembly according to the first aspect of the invention may be used advantageously for processing a semiconductor product, i.e., in a semiconductor process.

Accordingly, a second aspect of the invention relates to the usage of the process assembly according to the first aspect of the invention for processing a semiconductor product. By this means, such semiconductor processes may be performed in a particularly efficient manner. The long service life and high-temperature stability of the process assembly may secure reliable processing in an uncontaminated process volume even at high temperatures.

A method for processing a semiconductor product according to a third aspect of the invention comprises the steps of (i) depositing a semiconductor product within a process volume of a process tube of a process assembly according to the first aspect of the invention, (ii) sealing the process tube, and (iii) treating the semiconductor product within the process tube at a predetermined process temperature. Due to the support tube of the process assembly, the process tube, particularly the process volume, may remain stable during the treatment. Accordingly, this allows for a reliable and unimpaired processing of the semiconductor product.

For example, the semiconductor product such as a wafer may be placed, possibly along with many more semiconductor products, on a so-called “boat”. This boat may be inserted into the process tube and positioned inside the process volume. For example, the boat may be lifted into the process volume by means of a corresponding lifting device (a so-called “paddle”) and set down in the predetermined position on its boat feet such that the lifting device can be withdrawn from under the boat. Once the boat and the semiconductor product placed thereon are in a predetermined position, a lid may be used to close the process tube. Preferably, the lid seals the process tube in a gastight manner, such that the process volume can be evacuated. Further preferably, before, during or after the evacuation, the process volume may be heated, e.g., by means of a heating unit arranged circumferentially around the support tube. Subsequently, the semiconductor product may be processed in a defined process atmosphere and/or at a predetermined process temperature.

Other features which are considered as characteristic for the invention are set forth in the appended claims.

The properties, features and advantages of the invention described above, as well as the manner in which they are achieved, will be explained in more detail in connection with the figures in the following description of examples. Where appropriate, the same reference signs are used in the figures for the same or corresponding elements of the invention. The examples serve to explain the invention and do not limit the invention to the combinations of features indicated therein, even with respect to functional features. Moreover, any of the features disclosed in the above description as well as in the examples below may be considered in isolation and suitably combined with the features of any of the above embodiments and their further aspects. In particular, each of the features described above and below may be combined alone or in conjunction with others of the described features with the process assembly according to the first aspect of the invention, the usage according to the second aspect of the invention, and the method according to the third aspect of the invention.

That is, various modifications and structural changes may be made in the described invention without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a perspective view of an exemplary process assembly according to the invention;

FIG. 2 is a perspective view of a cross section of the process assembly;

FIG. 3 is a cross section of the process assembly of FIG. 2;

FIG. 4 is a schematic of exemplary forces acting on a process assembly;

FIG. 5 is a comparison between a conventional process tube and a process assembly comprising a support tube;

FIG. 6 is a flowchart of an exemplary method for processing a semiconductor product;

FIG. 7 an example of a longitudinal deformation of a support tube;

FIG. 8 a first example of a support tube comprising a nonlinear slit;

FIG. 9 a second example of a support tube comprising a nonlinear slit; and

FIG. 10 shows an example of a support tube comprising a toothed slit.

### DETAILED DESCRIPTION OF THE INVENTION

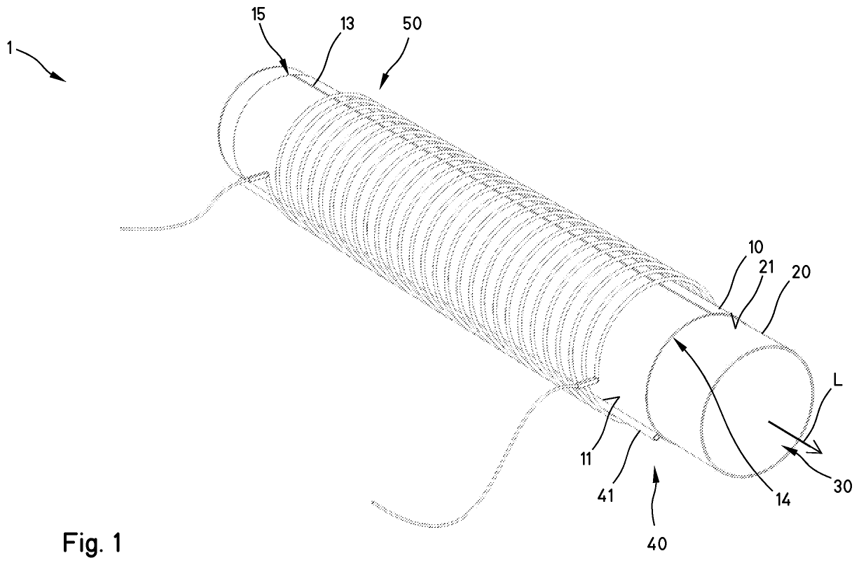

Referring now to the figures of the drawing in detail and first, in particular, to FIG. 1 thereof, there is shown an example of a process assembly 1 comprising a support tube 10 and a process tube 20 arranged at least sectionally within and supported by the support tube 10. The process tube 20 defines a process volume 30. The process assembly 1 further comprises a bearing structure 40 arranged on an outer surface 11 of the support tube 10, and a heating unit 50 arranged circumferentially around the support tube 10.

Both the support tube 10 and the process tube 20 are at least partially hollow tubes and coaxially aligned. The support tube 10 is seated on the process tube 20 such that the process tube 20 bears against the support tube 10. Particularly, at least a section of an outer surface 21 of the process tube 20 lies flat against an inner surface (not visible in FIG. 1) of the support tube 10. A perfect fit of the support tube 10 is achieved by providing a longitudinal slit 13 within the support tube 10. The slit 13 begins at a front end 14 of the support tube 10 and ends at a rear end 15 of the support tube 10. That is, the slit 13 traverses the entire length of the support tube 10.

In the present example, the process tube 20 extends between the two ends 14, 15 of the support tube 10 along the longitudinal direction L. For example, the support tube 10 may have at least 80% of the length of the process tube 20. Preferably, the ends 14, 15 of the support tube 10 define the ends of the process volume 30 within the process tube 20. In other words, the process volume 30 extends within the process tube 20 preferably over the length of the support tube 10, or the support tube 10 preferably has a length corresponding to a length of the process volume 30 within the process tube 20. By this means, temperature inhomogeneities within the process volume 30 may be prevented or at least reduced.

Advantageously, the process tube 20 is configured to receive a semiconductor product within the process volume 30. In the regions not covered by the support tube 10, the process tube 20 may comprise a respective lid (not shown) for sealing the process volume 30.

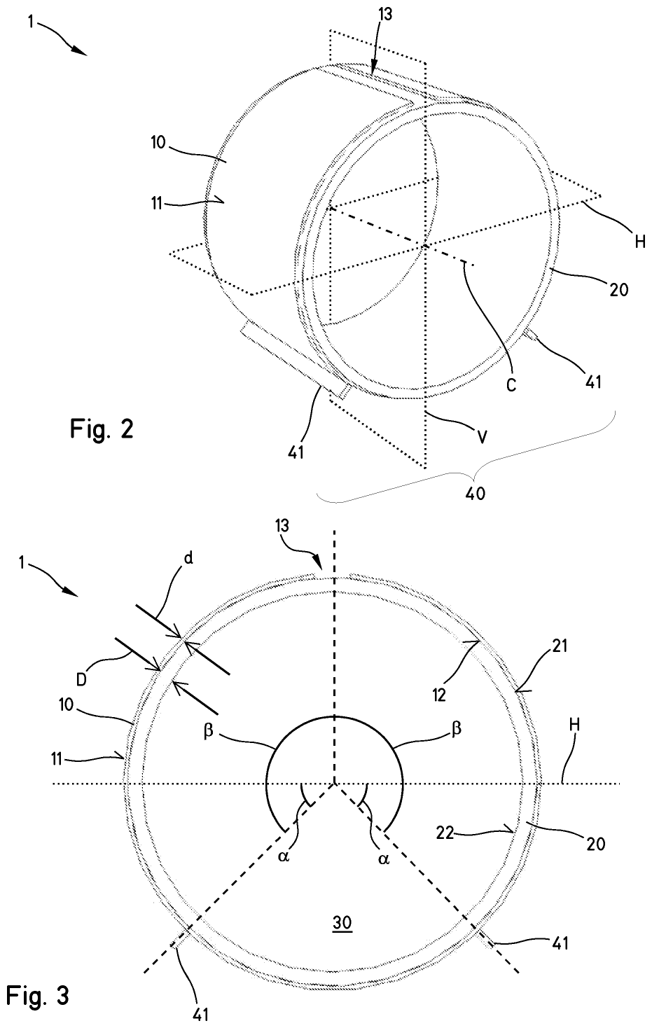

In the present example, the bearing structure 40 comprises a pair of bearing elements 41, of which only one is visible in FIG. 1. The bearing elements 41 are attached to the outer surface 11 of the support tube 10. The bearing elements 41 are configured as rails running along the entire length of the support tube 10. As shown in FIG. 1, the rails may be formed by tubes or rods with a diameter far smaller than the support tube 10. However, other shapes of the rails/bearing elements 41 are possible, as is shown in FIG. 2.

The bearing structure 40, particularly the bearing elements 41, bear the support tube 10 against the heating unit 50. The heating unit 50 comprises a heating element helically wound around the support tube 10. Preferably, the bearing structure 40, particularly the bearing elements 41, bridge a gap between the support tube 10 and the heating unit 50. For example, the bearing structure 40, particularly the bearing elements 41, are dimensioned such that when they bear the support tube 10 against the heating unit 50, the heating unit 50 and the support tube 10 are coaxial.

The process tube 20 is preferably fabricated from a material comprising quartz, which usually has good availability and is cost-effective. By having the support tube 10 being fabricated from a material comprising a ceramic, for example aluminum oxide, the support tube 10 can counterbalance plastic deformations of the process tube 20 at high temperatures, for example of 1,100° C. and above, as such a ceramic material may be dimensionally stable up to 1,300° C.

A ceramic support tube 10 also has the advantage of having good heat conductivity and being electrically insulating, thus preventing short circuiting the process tube 20 via the heating unit 50.

FIG. 2 shows an example of a section of a process assembly 1 comprising a support tube 10 and a process tube 20 coaxially aligned within and supported by the support tube 10. The support tube 10 is formed with a longitudinal slit 13. Further, a bearing structure 40 comprising a pair of bearing elements 41 is provided. The bearing elements 41 are formed by rails having a rectangular cross section.

The bearing elements 41 are symmetrically arranged on an outer surface 11 of the support tube 10 with respect to vertical median plane V of the support tube 10. The vertical median plane V extends through the slit 13, as the slit 13 is located at an apex of the support tube 10.

Further, the bearing elements 41 are arranged below a horizontal median plane H of the support tube 10. The vertical median plane V and the horizontal median plane H intersect along a center line C of the support tube 10.

FIG. 3 shows a head-on view of a cross section of the process assembly 1 of FIG. 2. The bearing elements 41 are arranged on the outer surface 11 of the support tube 10 below the horizontal median plane H at an angle α of substantially 45°. Accordingly, as the slit 13 is located at the apex of the support tube 10, the slit 13 and each of the bearing elements 41 enclose an angle β of substantially 135°. This configuration may provide a particularly stable positioning of the process assembly 1, in particular of the support tube 10 within the heating element (cf. FIG. 1).

In FIG. 3 it can also be seen that the wall thickness d of the support tube 10 is significantly smaller than the wall thickness D of the process tube 20. For example, the wall thickness d is at most 50%, preferably at most 30%, further preferably at most 10%, of the wall thickness D.

As can be further seen in FIG. 3, at least a part of an outer surface 21 of the process tube 20 lies flat against an inner surface 12 of the support tube 10. In other words, the process tube 20 is snugly fit inside the support tube 10. This is possible because the slit 13 enhances the elastic properties of the support tube 10 such that the support tube 10 can cling to the process tube 20. Particularly, the slit 13 provides flexibility to the support tube 10.

Preferably, a process volume 30 is circumferentially defined by an inner surface 22 of the process tube 20.

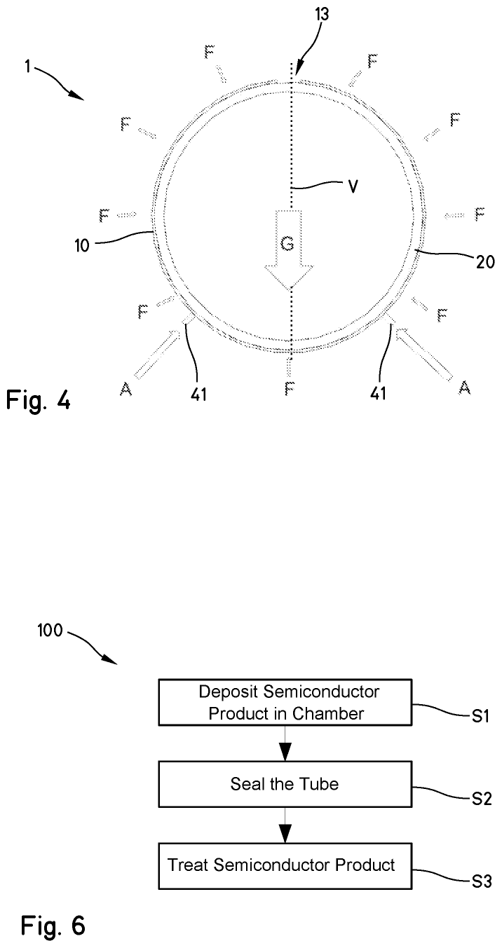

FIG. 4 shows an example of forces F, G, A acting on a process assembly 1 comprising a support tube 10, a process tube 20 and a pair of bearing elements 41. The support tube 10 is formed with a longitudinal slit 13 located at an apex of the support tube 10. The arrows representing the forces F, G, A show schematically their direction of action. Numeral G represents the weight force of the assembly 1, which acts on the center of mass. Numeral A represents bearing forces, which are transferred to the process tube 20 via the bearing elements 41 and the support tube 10. Further, F represents supporting forces, which act from the support tube 10 on the process tube 20 when supporting the process tube 20. By means of a symmetrical arrangement of the bearing elements 41 with respect to a vertical median plane V, the process tube 20 is snugly fit into the support tube 10.

Further, the longitudinal slit 13 in the support tube 10 facilitates elastic behavior of the support tube 10. Such elastic behavior may become relevant due to the different expansion coefficients of the support tube 10 and the process tube 20. During high-temperature operation, there may be a temperature gradient between the support tube 10 and the process tube 20, which may result in a bimetallic effect. Said bimetallic effect can lead to the support tube 10 curving towards the process tube 20, thereby acting resiliently on the process tube 20 and supporting it. The interaction of the weight force G and the bearing forces A reinforces this effect of snugging. As a result, the support tube 10 may be actively pressed against the process tube 20 by the forces A, G.

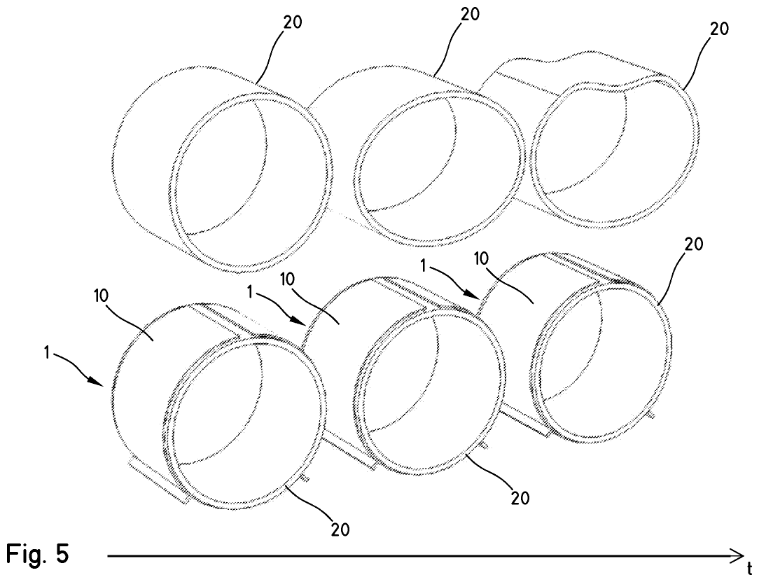

FIG. 5 shows a comparison between a conventional process tube 20 and a process assembly 1 comprising a support tube 10 for supporting the process tube 20 at different times t during high-temperature operation.

Conventional process tubes 20 are often fabricated from quartz. Quartz, however, becomes partially plastic at high temperatures such as 1,100° C. or more. If operated continuously or at least again and again at these high temperatures, the originally annular process tube 20 may flatten and become wider. The annular cross section becomes oval. If high-temperature operation continues further, the apex of the tube 20 may even begin to cave in, potentially obstructing the reception of semiconductor products for processing and/or causing an inhomogeneous temperature distribution within a process volume defined within the tube 20.

Such problems do not arise with the process assembly 1, as the process tube 20 is supported by the support tube 10. As shown in FIG. 5, the process tube 20 of the process assembly 1 does not deform, even after long operation at high temperatures such as 1,100° C.

This effect is achieved in particular by the design of the support tube 10 and by the interaction of the forces shown in FIG. 4 between the support tube 10 and the process tube 20. On the one hand, the process tube 20 may exhibit the aforementioned deformability during high-temperature operation. On the other hand, the support tube 10 is dimensionally stable even at high temperatures due to its material properties. To this end, the support tube 10 is preferably fabricated from a material comprising a ceramic, for example aluminum oxide.

FIG. 6 shows an example of a method 100 for processing a semiconductor product by means of a process assembly comprising a support tube and a process tube, wherein the process tube is at least sectionally arranged within the support tube such that the support tube supports the process tube.

In a method step S1, a semiconductor product is deposited within a process volume of the process tube of the process assembly. For example, the semiconductor product may be arranged on a boat, and said boat may be inserted into the process tube. Advantageously, this boat may act as an electrode within the process volume inside the process tube for generating a plasma. To this end, electrical ports may be provided within the process tube. An electrical connection between the ports and the boat may be established by sliding the boat into the process tube.

In method step S2, the process tube is sealed. This can be achieved by placing a lid onto an open end of the process tube. Preferably, this seals the process tube in a gas tight manner, such that the process volume can be evacuated subsequently.

For example, an evacuation pump coupled to the process tube may be operated accordingly, preferably until a predetermined process atmosphere, i.e., a predetermined vacuum pressure, is reached.

Alternatively or additionally, the temperature inside the process tube may be raised up to a predetermined process temperature. This may be achieved by accordingly operating a heating unit arranged close to the support tube, for example by operating a heating element helically wound around the support tube.

In a further method step S3, the semiconductor product is treated within the process volume. For example, a plasma can be generated inside the process tube. Due to the support tube supporting the process tube, the process volume can be kept dimensionally stable even over long periods of time and at elevated temperatures such as 1,100° C. or above.

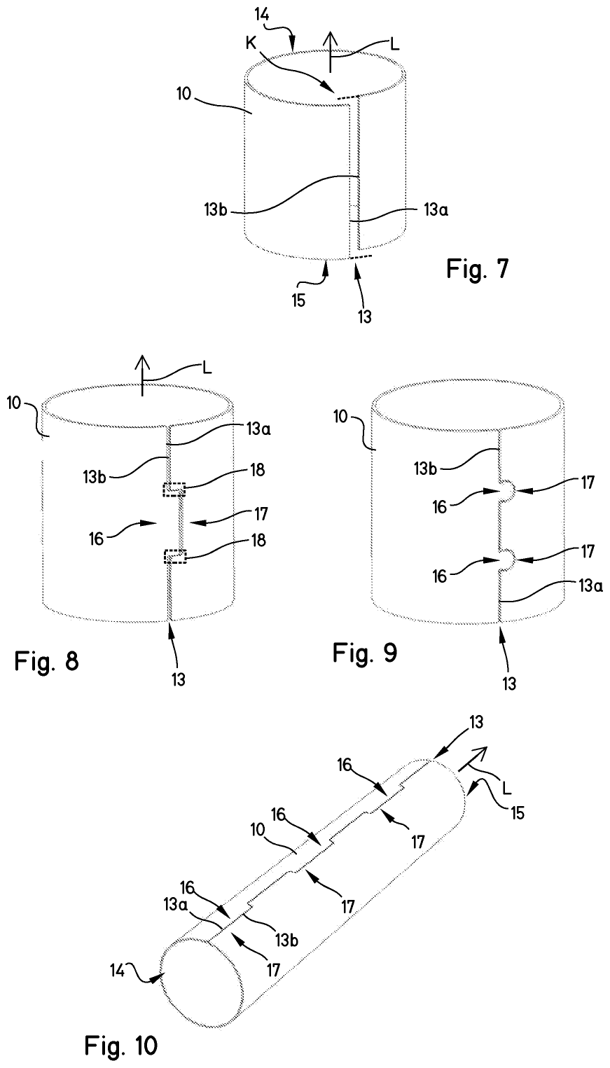

FIG. 7 shows an example of a longitudinal deformation K of the support tube 10. The deformation K may occur after long service life of the support tube 10. The deformation K is caused by a shift of two longitudinal edges 13a, 13b of the support tube 10 in the longitudinal direction L relative to each other. Said shift results in a helical form of the front end 14 and/or rear end 15 of the support tube 10. The dashed lines illustrate the associated longitudinal offset of both ends of the edge at the front or rear end 14, 15, respectively. Accordingly, the longitudinal deformation K shows some characteristics of torsional deformation.

In order to counter or at least reduce such deformation K, the support tube 10 may be provided with a nonlinear shape, as shown in FIGS. 8 to 10. Such nonlinear shape may cause an interlacing of the longitudinal edges 13a, 13b, providing increased stability against longitudinal deformation K.

FIG. 8 shows a first example of support tube 10 comprising a nonlinear slit 13. Said slit 13 is defined between two opposite longitudinal edges 13a, 13b of the support tube 10. One edge 13a comprises a projection 16, and the opposite edge 13b comprises a corresponding recess 17. In the present example, the projection 16 and the recess 17 are substantially rectangular. The projection 16 meshes with the recess 17, i.e. extends into the recess 17. As a result, sections 18 of the slit 13 (indicated by dashed rectangles) run substantially parallel to the longitudinal direction L.

Upon a longitudinal deformation as shown in FIG. 7, within one of the sections 18 of the slit 13, the longitudinal edge 13a may come into contact with the opposite longitudinal edge 13b. This blocks a further shift of the longitudinal edges 13a, 13b in the longitudinal direction L, hence effectively limiting the deformation of the support tube 10. Consequently, the width of the slit 13 may define a maximum possible longitudinal deformation. Preferably, the slit 13 is therefore provided with a small width. For example, the width of the slit is 10 mm or less, preferably 8 mm or less, further preferably 5 mm or less. Alternatively or additionally, the slit width is 1 mm or more, preferably 2 mm or more, further preferably 5 mm or more. Particularly, the slit width is between 1 mm and 10 mm.

Such rectangular shape of the projection 16 or recess 17, respectively, may be convenient in terms of fabrication, but is not mandatory for achieving the described effect. Other shapes are conceivable as well, as shown in FIG. 9. Likewise, as is shown in FIG. 10, more than one projection 16 or recess 17, respectively, may be provided as well.

FIG. 9 shows a second example of support tube 10 comprising a nonlinear slit 13 defined between two opposite longitudinal edges 13a, 13b of the support tube 10. One longitudinal edge 13a comprises two projections 16 having the semi-circular shape, while the opposite longitudinal edge 13b comprises two corresponding recesses 17. The projections 16 protrude into the recesses 17, resulting in a slit 13 having turns and angles. Accordingly, the two opposite edges 13a, 13b are interlaced and stabilize the support tube 10 against longitudinal deformation.

FIG. 10 shows an example of a support tube 10 having a toothed slit 13. Each tooth can be understood as being formed by a projection 16 of one of the two longitudinal edges 13a, 13b of the support tube 10, between which the slit 13 is defined. Except for the teeth at longitudinal ends 14, 15 of the support tube 10, each tooth of one edge 13a projects into a clearance between two teeth of the opposite edge 13b. Accordingly, these clearances may be understood as recesses 17.

Having such a plurality of projections 16 or recesses 17, respectively, in particular forming a toothed slit 13, may help increasing the resilience of the support tube 10 against longitudinal deformation. This is achieved by effectively increasing the total length of the slit 13 and increasing the number of sections where the slit 13 runs substantially perpendicular or at least at an angle to the longitudinal direction L.

The following is a summary list of reference numerals and the corresponding structure used in the above description of the invention:
1 process assembly
10 support tube
11 outer surface
12 inner surface
13 slit
13a, 13b longitudinal edge
14 front end
15 rear end
16 projection
17 recess
18 section
20 process tube
21 outer surface
22 inner surface
30 process volume
40 bearing structure
41 bearing element
50 heating unit
100 method
S1-S3 method steps
H horizontal median plane
V vertical median plane
C center line
L longitudinal direction
t time
D, d wall thickness
K deformation
F, G, A forces
α, β angles

1. A process assembly for processing a semiconductor product, the process assembly comprising:
a hollow support tube, said support tube being formed with a slit running along a longitudinal direction of said support tube; and
a hollow process tube defining a process volume for a semiconductor process, said process tube being arranged, at least sectionally, within said support tube and said support tube supporting said process tube.

2. The process assembly according to claim 1, wherein an inner surface of said support tube lies flat against an outer surface of said process tube at least sectionally.

3. The process assembly according to claim 1, wherein said support tube is arranged coaxial with said process tube.

4. The process assembly according to claim 1, wherein said slit is formed to intersect said support tube over an entire length of said support tube.

5. The process assembly according to claim 1, wherein a width of said slit covers between 2% and 10% of an outer circumference of said support tube.

6. The process assembly according to claim 1, wherein the width of the slit covers approximately 6% of the outer circumference of said support tube. preferably 4% to 8%

7. The process assembly according to claim 1, wherein said slit is a nonlinear slit (straight-line).

8. The process assembly according to claim 1, wherein said support tube comprises at least one section in which said slit runs substantially perpendicular to the longitudinal direction or at least encloses a non-zero an angle with the longitudinal direction.

9. The process assembly according to claim 1, wherein said slit is defined by two opposite longitudinal edges of said support tube, one of said edges being formed with at least one projection configured to at least partially mesh with a corresponding recess formed in an opposite edge.

10. The process assembly according to claim 1, wherein said support tube further comprises a bearing structure for bearing said support tube, said bearing structure being arranged on an outer surface of said support tube.

11. The process assembly according to claim 1, wherein said support tube comprises at least two bearing elements arranged on an outer surface of said support tube.

12. The process assembly according to claim 11, wherein said at least two bearing elements are arranged below a horizontal median plane of said support tube.

13. The process assembly according to claim 12, wherein, relative to a center line of said support tube, each of said at least two bearing elements is arranged at an angle of substantially 45° below the horizontal median plane of said support tube.

14. The process assembly according to claim 11, wherein said at least two bearing elements are arranged on the outer surface of said support tube symmetrically with respect to a vertical median plane of said support tube.

15. The process assembly according to claim 11, wherein said at least two bearing elements are said rails running along the longitudinal direction.

16. The process assembly according to claim 10, wherein said support tube and said bearing structure are fabricated in one piece.

17. The process assembly according to claim 1, wherein at least one of the following is true: said process tube is fabricated from a material comprising quartz or said support tube is fabricated from a material comprising a ceramic.

18. The process assembly according to claim 1, wherein a wall thickness of said support tube is less than 50% of a wall thickness of said process tube. preferably less than 30%, further preferably less than 10%,

19. The process assembly according to claim 1, further comprising a heating unit arranged circumferentially around said support tube.

20. A method for processing a semiconductor product, the method which comprises:
providing the process assembly according to claim 1;
depositing a semiconductor product within a process volume of the process tube of the process assembly;
sealing the process tube; and
treating the semiconductor product within the process tube at a predetermined process temperature.
